(19) United States
(12) Patent Application Publication
(10) Pub. No.: US 2025/0305123 A1
(43) Pub. Date: Oct. 2, 2025

(54) METHOD AND APPARATUS FOR FORMING PROTECTIVE FLUORIDE LAYER ON PART HAVING GAS FLOW PASSAGE FOR SEMICONDUCTOR DEPOSITION APPARATUS

(71) Applicant: WONIK QNC Corporation, Gumi-si (KR)

(72) Inventors: Eun Young CHOI, Hwaseong-si (KR); Joo Hee JANG, Hwaseong-si (KR); Dong Ho SHIN, Seoul (KR); Min Seob JUNG, Seoul (KR)

(73) Assignee: WONIK QNC Corporation, Gumi-si (KR)

(21) Appl. No.: 19/073,920

(22) Filed: Mar. 7, 2025

(30) Foreign Application Priority Data
Mar. 27, 2024 (KR) 10-2024-0041489

(51) Int. Cl. C23C 16/44; C23C 16/52; H01J 37/32

(52) U.S. Cl. CPC C23C 16/4404; C23C 16/52; H01J 37/32449; H01J 37/32477; H01J 37/32522; H01J 37/32541; H01J 2237/3321

(57) ABSTRACT

Disclosed are a method and an apparatus for forming a protective fluoride layer for a part having a gas flow passage for a semiconductor deposition apparatus, and a part having a gas flow passage for a semiconductor deposition apparatus, which has a protective fluoride layer formed thereby. The method includes: a part placement step of placing the part in a process chamber; a process gas introduction step of introducing process gases for forming a protective fluoride layer into the process chamber; a plasma heat treatment step of applying heat and plasma to the process chamber; and a process control step of controlling process parameters of the process gas introduction step and the plasma heat treatment step so that a protective fluoride layer with a predetermined thickness is formed on the surface of the part and in the gas flow passages and the holes.

### BACKGROUND

### 1. Technical Field

The present disclosure relates to a method for forming a protective fluoride layer for a part having a gas flow passage for a semiconductor deposition apparatus, a part having a gas flow passage for a semiconductor deposition apparatus, which has a protective fluoride layer formed thereby, and an apparatus for forming a protective fluoride layer on a part having a gas flow passage for a semiconductor deposition apparatus. More specifically, the present disclosure relates to a method for forming a protective fluoride layer on a part having a gas flow passage for a semiconductor deposition apparatus, which, by performing plasma heat treatment using process gases including a CF₄ reactive gas under specific process conditions, may form a stable protective AlFₓ layer on the surface and in the holes of a showerhead which is a part having a gas flow passage for a semiconductor deposition apparatus, and in particular, may form the protective fluoride layer with a controlled content and thickness, a part having a gas flow passage for a semiconductor deposition apparatus, which has a protective fluoride layer formed by the method, and an apparatus for forming a protective fluoride layer on a part having a gas flow passage for a semiconductor deposition apparatus.

### 2. Related Art

In general, semiconductor devices are manufactured through a number of unit processes such as an ion implantation process, a thin film deposition process, a diffusion process, a photolithography process, and an etching process. Among these unit processes, the thin film deposition process is an essential process that requires improvement in the reproducibility and reliability of semiconductor device manufacturing.

Thin films of semiconductor devices are formed on wafers by sputtering, evaporation, chemical vapor deposition (CVD), atomic layer deposition (ALD), etc.

A thin film deposition apparatus for performing this method typically includes a reactor, gas lines for supplying various gases into the reactor, a shower ring, a showerhead, and a wafer block on which a wafer is mounted.

Recently, as the substrate size has become larger, the importance of the uniformity of the thin film deposited on the substrate has increased. However, when a gas supply pipe or a shower ring is used, the uniformity of the thin film deposited on the substrate is not superior to that when a showerhead is used. Therefore, a showerhead or a combination of a showerhead and a shower ring is generally used as a gas supply device in the chemical vapor deposition method.

In order to deposit a thin film on a semiconductor substrate, a vacuum chamber is mostly used, and to improve the characteristics of the thin film deposition process and increase productivity, plasma or reactive gases are used in the chamber. Thus, aluminum (Al), which has good electrical conductivity and corrosion resistance, is generally used as the chamber material and the material of the parts inside the chamber.

However, corrosion resistance deteriorates due to pin holes or burrs generated during processing of parts made of aluminum, or reaction by-products easily adhere, changing process characteristics or generating impurity particles.

Therefore, in order to overcome these problems, a technology for coating the parts in the chamber using an anodizing method has been disclosed. However, in a thin film deposition environment at high temperatures, the anodizing film peels off after a certain period of time due to the difference in coefficient of thermal expansion between aluminum and the anodizing film, resulting in problems such as the generation of impurity particles and the disruption of the process.

Recently, Al has been used in a bare state with the existing problems as they are. While the thermal expansion coefficient of Al is large at 23.03×10⁻⁸/° C., the thermal expansion coefficient of the anodizing film is 6.87×10⁶ at 20° C. to 100° C. and 8.33×10⁶ at 20° C. to 500° C. Although the thermal expansion coefficient of the anodizing film increases in proportion to the temperature, it significantly differs from that of Al, and the problem of film peeling caused by this difference has not yet been overcome.

As materials for parts inside a semiconductor vacuum chamber that may be used as specific coating-target base materials for semiconductor equipment, Al, Ni, and Hastelloy and Inconel, which are types of Ni alloys, are used. Recently, much effort has been made to overcome the problem of corrosion caused by reactive gas and particle problems caused by accumulation of reaction by-products.

However, in the case of anodizing and thermal spray coating, which are commonly used in a conventional art, the coating film peels off over time due to the difference in thermal expansion coefficient from that of the metal base material, causing secondary problems. Thus, other alternatives are needed.

In particular, in the case of a showerhead, which is a part in a semiconductor vacuum chamber, it is located directly above a wafer for depositing a thin film. Thus, if the surface condition changes due to corrosion or reaction by-products are accumulated and deposited, particles are easily generated, and thus a continuous CVD process cannot be performed and frequent ex-situ cleaning is required.

However, in a conventional art, when cleaning a showerhead, the cleaning gas NF₃ reacts with the cleaning-target material, aluminum alloy (Al alloy), to form AlF₃. Due to the continuous reaction of NF₃ and Al and the high-temperature instability of AlF₃, the cycle is repeated for thermal change (O reaction), and thus a problem arises in that particles are generated inside the chamber due to frequent cycle changes of Al—O and Al—F. In addition, there is a problem in that, as the process progresses and the amount of impurities in the Al showerhead increases, the emissivity changes, and thus the temperature received by the wafer due to the radiant heat of the Al showerhead may change, leading to a change in the deposition thickness of the wafer.

As part of an effort to solve these problems, a technology for forming a protective film or layer on a part (component) has been proposed.

As an example of a conventional method for forming a fluorinated layer, a method is known in which a part to be fluorinated is placed in a vacuum chamber, and then a low-pressure vacuum plasma is generated using a fluorine-containing gas such as CF₄, SF₆, or NF₃, so that the surface is fluorinated by fluorine-containing radicals (“Fabrication, characterization, and fluorine-plasma exposure behavior of dense yttrium oxyfluoride ceramic”, T Tsunoura et al., Japanese Journal of Applied Physics 56, 06HC02 (2017), “Fluorination mechanisms of Al2O3 and Y2O3 surfaces irradiated by high-density CF₄/O₂ and SF₆/O₂ plasmas”, K Miwa et al, J Vac Sci Technol A 27(4), July/August 2009).

However, this method has disadvantages in that it requires the construction of a vacuum chamber and corresponding vacuum devices, which is disadvantageous for mass production and results in low economic feasibility, and in that, since it uses a low-pressure plasma process, the density of fluorine-containing radicals is low, and thus the fluorination rate is low, leading to low productivity.

As another example, a method is known in which a part to be fluorinated is immersed in a solution of HF, SF₄, CHF₃ or the like, and then the surface thereof is fluorinated by increasing the temperature to about 250° C. (“Preparation of Fluorinated-Alumina”, E Kemnitz et al., “Efficient Preparations of Fluorine Compounds”, Edited by H W Roesky, 2013, 442)

However, this method has a disadvantage in terms of process safety because it uses a hazardous solution during the handling and treatment processes.

In addition, as other examples, U.S. Pat. No. 8,206,829 and/or US Patent Application Publication No. 2017/0114440 are known. These documents disclose a method of coating the surface of a part with a powder material such as AlF₃, YF₃, AlOF, or YOF by a method such as plasma spraying.

However, there is a disadvantage in that, since the raw material price of AlF₃ or YF₃, which is a coating raw material used for a ceramic protective coating such as alumina (Al₂O₃) or yttria (Y₂O₃), is very high and the supply of the raw material is not smooth as the raw material suppliers are limited, economic feasibility is low.

### PATENT DOCUMENTS

Korean Patent No. 10-1309716 (published on Sep. 17, 2013)
Korean Patent No. 10-1465640 (published on Nov. 28, 2014)
U.S. Pat. No. 8,206,829 (registered on Jun. 26, 2012)
US Patent Application Publication No. 2017/0114440 (published on Apr. 27, 2017)

### SUMMARY

Therefore, the present disclosure has been made in order to solve the above-described problems occurring in the prior art, and an object of the present disclosure is to provide a method for forming a protective fluoride layer on a part having a gas flow passage for a semiconductor deposition apparatus, which, by performing plasma heat treatment using process gases including a CF₄ reactive gas under specific process conditions, may form a stable protective AlFₓ layer on the surface and in the holes of a showerhead which is a part having a gas flow passage for a semiconductor deposition apparatus, and in particular, may form the protective fluoride layer with a controlled content and thickness, a part having a gas flow passage for a semiconductor deposition apparatus, which has a protective fluoride layer formed by the method, and an apparatus for forming a protective fluoride layer on a part having a gas flow passage for a semiconductor deposition apparatus.

In accordance to one aspect of the present disclosure for achieving the objects and other features of the present disclosure, there is provided a method for forming a protective fluoride layer on a part having a gas flow passage for a semiconductor deposition apparatus, the part including a showerhead having a gas flow passage and a plurality of holes, the method including: a part placement step of placing a part having a gas flow passage in a process chamber; a process gas introduction step of introducing process gases for forming a protective fluoride layer into the process chamber; a plasma heat treatment step of applying heat and plasma to the process chamber; and a process control step of controlling process parameters of the process gas introduction step and the plasma heat treatment step so that a protective fluoride layer with a predetermined thickness is formed on the surface of the part having the gas flow passage and in the gas flow passage and the holes.

In one embodiment of the present disclosure, the process control step may include controlling a combination of a plurality of process parameters among process parameters, including process gas introduction amounts, plasma generation power, treatment time, heat treatment temperature, working vacuum level, the distance between plasma and the part, and the number of treatment cycles.

In one embodiment of the present disclosure, the process control step may include controlling the process parameters so that the protective fluoride layer is formed to a thickness of 200 nm to 500 nm.

In one embodiment of the present disclosure, the process parameters that are controlled in the process control step preferably include a plasma generation power of 100 W, a heat treatment temperature of 200° C. to 600° C., a working vacuum level of 10 mTorr to 20 mTorr, and a treatment time of 1 hour to 3 hours.

In one embodiment of the present disclosure, the process parameters that are controlled in the process control step may include a plasma generation power of 1 kW to less than 3 kW, a flow rate ratio between non-fluorine reactive gas (O₂) and fluorine-containing reactive gas (CF₄) of 0 to 10:90 to 100, a distance between plasma and the part of 30 to 50 mm, a treatment time of 15 to 60 minutes, and a cycle number of 1 to 4 cycles, and the process control step may be performed using a floating plasma source method for forming a floating potential.

In accordance with another aspect of the present disclosure, there is provided a part having a gas flow passage for a semiconductor deposition apparatus, which has a protective fluoride layer formed by the above-described method for forming a protective fluoride layer on a part having a gas flow passage for a semiconductor deposition apparatus.

In accordance with still another aspect of the present disclosure, there is provided an apparatus for forming a protective fluoride layer on a part having a gas flow passage for a semiconductor deposition a apparatus, the part including showerhead having a gas flow passage and a plurality of holes, the apparatus for forming the protective fluoride layer including: a process chamber body; a process gas inlet provided on one side of the process chamber body and configured to introduce process gases; a process gas outlet provided on the other side of the process chamber body and configured to discharge process gases; a heating member provided in the process chamber body; an electrode member provided in the process chamber body; and a plasma up-down device connected to the electrode member.

In one embodiment of the present disclosure, the process gas inlet is provided at a central portion of the upper side of the process chamber body, the process gas outlet is provided at a central portion of the lower side of the process chamber body, and the electrode member may be provided opposite to the heating member at a predetermined distance therefrom.

In one embodiment of the present disclosure, the electrode member may be composed of a plurality of ring-shaped electrodes arranged at a distance from each other in a radial direction concentrically around the center.

In one embodiment of the present disclosure, the electrode member may have a spiral shape, a coil shape, or a plate shape.

In one embodiment of the present disclosure, the heating member may be composed of a plate-shaped heater on which the part having the gas flow passage is placed.

In one embodiment of the present disclosure, the apparatus may further include, at a process gas inlet side, a diffusion member that allows the process gases introduced through the process gas inlet to diffuse.

The method for forming a protective fluoride layer on a part having a gas flow passage for a semiconductor deposition apparatus according to the present disclosure, a part having a gas flow passage for a semiconductor deposition apparatus, which has a protective fluoride layer formed by the method, and an apparatus for forming a protective fluoride layer on a part having a gas flow passage have the following effects.

First, the present disclosure has the effect of forming a stable protective fluoride layer on the surface and in the holes of a showerhead, which is a part having a gas flow passage and a plurality of gas injection holes.

Second, the present disclosure has the effect of forming a protective fluoride layer with a controlled content and/or thickness by controlling the heat treatment temperature and reaction time.

Third, the present disclosure has the effect of drastically reducing the amount of by-products and particles adhering to the surface or holes of a part having a gas flow passage, and preventing a shift in process conditions from occurring when cleaning with a fluorine-containing cleaning gas (in-situ dry cleaning (ISD)).

Fourth, the present disclosure has the effect of extending the life of a part by preventing a protective layer formed on the surface and in the holes of the part from being detached and protecting the part from plasma cleaning gas.

### BRIEF DESCRIPTION OF THE DRAWINGS

FIG. 1 is a flowchart schematically showing a method for forming a protective fluoride layer on a part having a gas flow passage for a semiconductor deposition apparatus according to the present disclosure.

FIG. 2 is a conceptual view schematically showing a state in which a protective fluoride layer is formed in the holes of a part having a gas flow passage through a method for forming a protective fluoride layer on a part having a gas flow passage for a semiconductor deposition apparatus according to the present disclosure.

FIG. 3 is a cross-sectional perspective view showing the configuration of an apparatus for forming a protective fluoride layer on a part having a gas flow passage for a semiconductor deposition apparatus according to the present disclosure.

FIG. 4 is a table showing the results of comparing the surface microstructure and the Mg and F contents depending on the plasma heat treatment temperature and the treatment time.

FIG. 5 is a table showing the results of XRD analysis depending on the plasma heat treatment temperature and the treatment time.

FIG. 6 is a table showing the results of XPS analysis for depth depending on the plasma heat treatment temperature and the treatment time.

FIG. 7 is a table showing the results of analyzing the binding energy of a protective fluoride layer depending on the plasma heat treatment temperature and the treatment time.

FIG. 8 is a table showing the results of an experiment on the formation of a protective fluoride layer using the process parameters of a second embodiment.

FIG. 9 is a table showing the results of an experiment on the formation of a protective fluoride layer on the surface and in the holes using the process parameters of the second embodiment.

### DETAILED DESCRIPTION

Specific embodiments according to the present disclosure will be described below with reference to the accompanying drawings.

However, this is not intended to limit the invention to any particular embodiment, and is to be understood to include all modifications, equivalents, and substitutions that fall within the idea and technical scope of the invention.

Throughout the specification, parts having like construction and operation are designated by the same reference signs. In addition, the accompanying drawings of the present disclosure are for the convenience of illustration only, and shapes and relative dimensions thereof may be exaggerated or omitted.

In describing embodiments in detail, redundant descriptions or descriptions of techniques that are obvious in the field are omitted. In addition, whenever any part is the to “include” other components in the following description, it is intended to include components in addition to those listed, unless the contrary is specifically indicated.

In addition, terms such as “part,” “section,” “module,” and the like used herein mean a unit that performs at least one function or operation, which may be implemented in hardware, software, or a combination of hardware and software. Also, when one part is the to be electrically connected to another part, this includes direct connections as well as connections with other configurations in between.

Terms containing ordinal numbers, such as first, second, and the like, may be used to describe various components, but the components are not limited by such terms. These terms are used only to distinguish one component from another. For example, a second component may be named as a first component, and similarly, a first component may be named as a second component, without departing from the scope of the present disclosure.

Hereinafter, a method for forming a protective fluoride layer on a part having a gas flow passage for a semiconductor deposition apparatus according to preferred embodiments of the present disclosure, a part having a gas flow passage for a semiconductor deposition apparatus, which has a protective fluoride layer formed thereby, and an apparatus for forming a protective fluoride layer on a part having a gas flow passage for a semiconductor deposition apparatus will be described in detail with reference to the accompanying drawings.

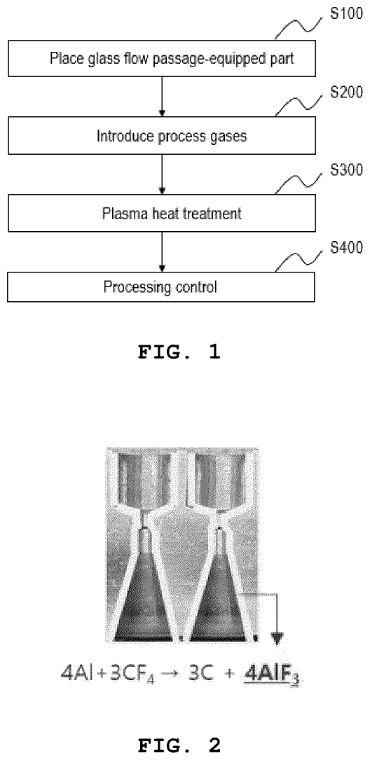

First, a method for forming a protective fluoride layer on a part having a gas flow passage for a semiconductor deposition apparatus according to the present disclosure will be described in detail with reference to FIG. 1.

FIG. 1 is a flowchart schematically showing a method for forming a protective fluoride layer on a part having a gas flow passage for a semiconductor deposition apparatus according to the present disclosure, and FIG. 2 is a conceptual view schematically showing a state in which a protective fluoride layer is formed in the holes of a part having a gas flow passage through a method for forming a protective fluoride layer on a part having a gas flow passage for a semiconductor deposition apparatus according to the present disclosure.

The method for forming a protective fluoride layer on a part having a gas flow passage for a semiconductor deposition apparatus according to the present disclosure is a method for forming a protective fluoride layer (protective fluoride film) on a part having a gas flow passage, the part including a showerhead that is used in a semiconductor deposition apparatus, and as shown in FIGS. 1 and 2, the method generally includes a part placement step (S100), a process gas introduction step (S200), a plasma heat treatment step (S300), and a process control step (S400).

Specifically, the method forming a protective fluoride layer on a part having a gas flow passage for a semiconductor deposition apparatus according to the present disclosure is a method for forming a protective fluoride layer (protective fluoride film) on a part having a gas flow passage, the part including a showerhead which is used in a semiconductor deposition apparatus and has a gas flow passage and a plurality of holes, and as shown in FIGS. 1 and 2, the method includes: a part placement step (S100) of placing a part having a gas flow passage in a process chamber having a treatment space for forming a protective fluoride layer using an apparatus for forming a protective fluoride layer; a process gas introduction step (S200) of introducing the discharge gas Ar, the non-fluorine reactive gas O₂, and CF₄ reactive gas, which are process gases, into the treatment space of the process chamber in which the part is placed in the part placement step (S100); a plasma heat treatment step (S300) in which plasma generation power is applied to the processing space of the processing chamber to generate plasma in the processing space while maintaining a thermal environment of a predetermined temperature; a plasma heat treatment step (S300) of applying plasma generation power to the treatment space of the process chamber to generate plasma in the treatment space while creating a thermal environment with a predetermined temperature in the treatment space; and a process control step (S400) of controlling a combination of a plurality of process parameters among process parameters, including the amounts of gases introduced in the process gas introduction step (S200), the power for plasma generation performed in the plasma heat treatment step (S300), the treatment time, the heat treatment temperature, the working pressure (i.e., the working vacuum level), the distance between plasma and the part (the distance between the plasma generating unit and the part), and the treatment time, a control module unit so that a protective fluoride layer with a predetermined thickness (or depth) is formed on the surface of the part and in the gas flow passage and the holes.

The part placement step (S100) is, for example, a process of placing a fluorination-target part to be exposed to plasma in a treatment chamber having a plasma reaction space (treatment space), and may be performed by placing a fluorination-target part to be fluorinated on the top of a support located in the treatment space and closing the door of the treatment chamber to isolate the inside of the treatment space from the outside.

The apparatus for forming a protective fluoride layer, which has a process chamber used in the part placement step (S100), will be described in detail below.

Next, the process gas introduction step (S200) is a process of introducing the discharge gas Ar, the non-fluorine reactive gas O2, and CF₄ reactive gas, which are process gases, into the treatment space at flow rates controlled in the process control step (S400).

In the process gas introduction step (S200), in addition to Ar gas, an inert gas such as He, Ne, Ar, Kr, or Xe may be used as the discharge gas. Also, in addition to oxygen (O₂) gas, nitrogen (N₂), air, or the like may be used as the non-fluorine reactive gas. Also, in addition to the fluorine-containing reactive gas CF₄, a carbon fluoride gas such as C₂F₆ or C₄F₈, or nitrogen trifluoride (NF₃) gas, etc. may be used. However, in the present disclosure, preferably, argon (Ar) gas is used as the discharge gas, oxygen (O₂) is used as the non-fluorine reactive gas, and carbon tetrafluoride (CF₄) is used as the fluorine-containing reactive gas.

Next, the plasma heat treatment step (S300) is performed by applying a predetermined plasma generation power through a plasma generator to generate plasma in the treatment space while creating a thermal environment with a predetermined temperature in the treatment space using a heating member provided in the treatment space.

The plasma heat treatment step (S300) is performed while the process parameters for plasma generation and heat treatment are controlled by the process control step (S400) described below.

Next, the process control step (S400) is performed by controlling a combination of a plurality of process parameters, including the amounts of gases introduced in the process gas introduction step (S200), plasma and heat treatment-related parameters of the plasma heat treatment step (S300), the working vacuum level, the distance between plasma and the part (distance between the electrode to which plasma RF voltage is applied and the target part), and the treatment cycle.

In the present disclosure, the process control step (S400) may be performed using various methods which are classified, according to the type of plasma source used in the known plasma etching process, into a reactive ion etching (RIE) method, a plasma etching (PE) method, and a remote plasma source (RPS) method, and may be performed using a floating plasma source method for forming a floating potential.

In the present disclosure, the processing control step (S400) is preferably performed so that a protective fluoride layer (AlF layer) is formed on the surface and in the gas flow passage and the holes to a thickness (depth) of 200 nm to 500 nm.

Specifically, in a first embodiment in which the process parameters are controlled so that a protective fluoride layer with the above-described thickness is formed, the process parameters that are controlled in the process control step (S400) include a plasma generation power of 100 W, a heat treatment temperature (i.e., part temperature) of 200° C. to 600° C. (preferably 250° C. to 300° C.), a working vacuum level of 10 mTorr to 20 mTorr, and a treatment time of 1 hour to 3 hours (preferably 1 hour to 2 hours).

In addition, in a second embodiment in which the process parameters are controlled so that a protective fluoride layer with the above-described thickness is formed, the process parameters that are controlled in the process control step (S400) include a plasma generation power of 1 kW to less than 3 kW, a flow rate ratio between non-fluorine reactive gas (O₂) and fluorine-containing reactive gas (CF₄) of 0 to 10:90 to 100, a distance between plasma and the part (distance between the electrode to which plasma RF voltage is applied and the target part) of 30 to 50 mm (preferably 40 mm), a treatment time of 8 to 20 minutes (preferably 10 to 15 minutes), and a cycle number of 1 to 4 cycles.

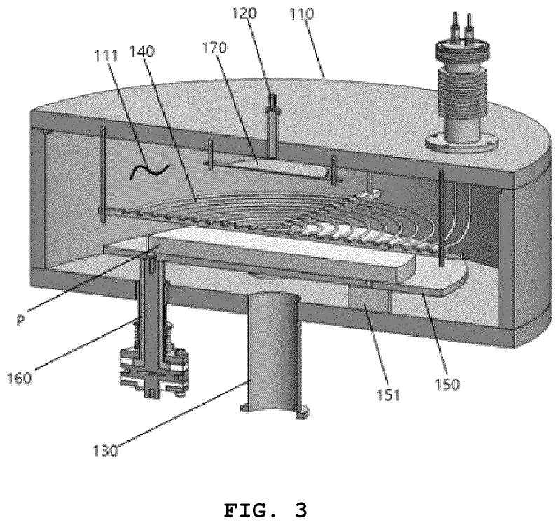

An apparatus for forming a protective fluoride layer on a part having a gas flow passage for a semiconductor deposition apparatus according to the present disclosure will now be described with reference to FIG. 3. FIG. 3 is a cross-sectional perspective view showing the configuration of an apparatus for forming a protective fluoride layer on a part having a gas flow passage for a semiconductor deposition apparatus according to the present disclosure.

As shown in FIG. 3, the apparatus for forming a protective fluoride layer on a part having a gas flow passage for a semiconductor deposition apparatus according to the present disclosure includes: a process chamber body 110 having a treatment space 111 therein; a process gas inlet 120 provided on one side (upper side in the drawing) of the process chamber body 110 and configured to introduce process gases into the treatment space 111; a process gas outlet 130 provided on the other side (lower side in the figure) of the process chamber body 110 and configured to discharge process gases; an electrode member (power electrode member) 140 provided in the process chamber body 110; a heating member 150 provided opposite to the electrode member 140 in the process chamber body 110; and a plasma up-down device (or stage height adjustment device) 160 coupled to, for example, the heating member 150 so as to adjust the distance between plasma and the part having the gas flow passage. Here, the plasma up-down device 160 may be omitted.

The process chamber body 110 is formed in a cylindrical shape, has, on one side thereof, an opening/closing portion (not shown) that opens/closes to load the part having the gas flow passage, and is configured so that the inside thereof is kept airtight when closed by the opening/closing portion.

The process gas inlet 120 may be provided at the central portion of the upper side of the process chamber body 110, and the process gas outlet 130 may be provided at the central portion of the lower side of the process chamber body 110.

The electrode member 140 may be formed in a shape corresponding to a plate-shaped part such as a showerhead. Preferably, the electrode member 140 may be composed of a plurality of ring-shaped electrodes arranged at a distance from each other concentrically around the center of the process chamber body 110 as shown in the figure, and may be configured to be mounted on a cross-shaped mounting means 141.

In addition, the electrode member 140 may have a spiral shape, a coil shape, or a plate shape.

The heating member 150 may preferably be composed of a plate-shaped ceramic heater on which the part (P) having the gas flow passage is placed.

In addition, since the process gas outlet 130 is formed at the central portion of the lower side, plasma up-down device 160 is coupled to one side edge of the heating member 150, and accordingly, the other side of the heating member 150 is supported by a support 151. The support 151 is configured to support the lower surface of the other side of the heating member 150 in conjunction with the up-down movement of the plasma up-down device 160. For example, the lower portion of the support 151 may be provided within a housing and configured to be elastically supported upward by an elastic member provided within the housing.

Meanwhile, the apparatus for forming a protective fluoride layer on a part having a gas flow passage for a semiconductor deposition apparatus according to the present disclosure may further include, at the process gas inlet 120 side in the treatment space 111 of the process chamber body 110, a diffusion member 170 that allows the process gases introduced through the process gas inlet 120 to diffuse.

The diffusion member 170 may be composed of a diffusion plate provided at a certain distance from the injection end of the process gas inlet 120, wherein the diffusion plate may be formed in a plate shape as shown in the figure, and may be composed of a dome-shaped plate or a triangular plate.

The apparatus for forming a protective fluoride layer on a part having a gas flow pathway for a semiconductor deposition apparatus forms a protective fluoride layer with a predetermined thickness on a part having a gas flow passage by controlling a combination of a plurality of process parameters among process parameters, including process gas introduction amounts, plasma generation power, treatment time, heat treatment temperature, working vacuum level, and the number of treatment cycles, through an external control module unit.

Meanwhile, the inventor of the present disclosure conducted experiments on a protective fluoride layer obtained through the control process included in the method for forming a protective fluoride layer on a part having a gas flow passage for a semiconductor deposition apparatus according to the present disclosure. The experimental results will now be described.

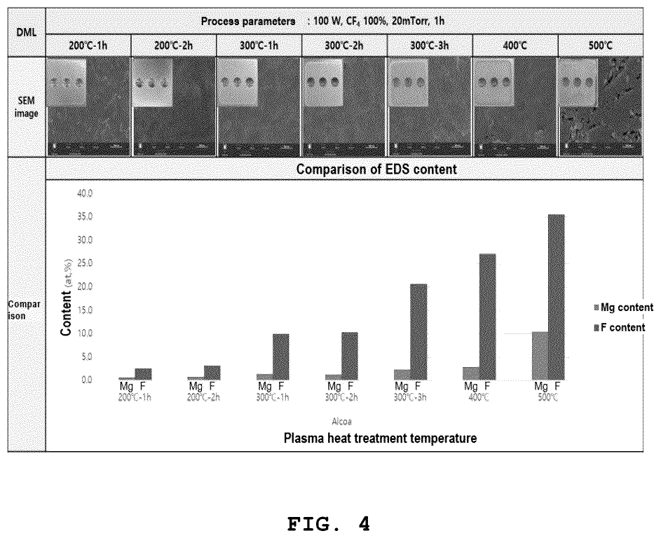

First, the experimental results for the protective fluoride layer obtained through the method of forming a protective fluoride layer using the process parameters of the first embodiment will be described with reference to FIGS. 4 to 7.

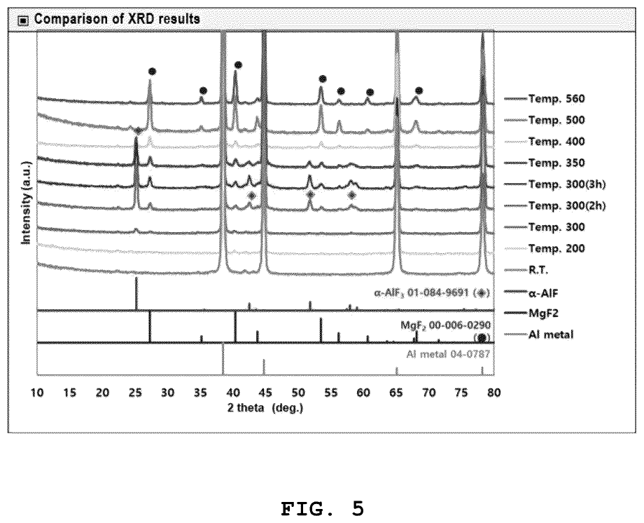

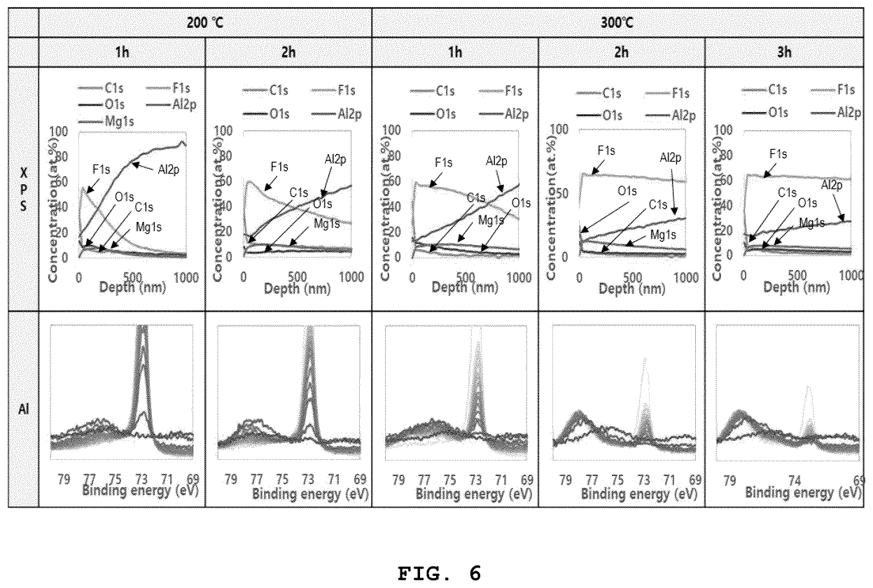

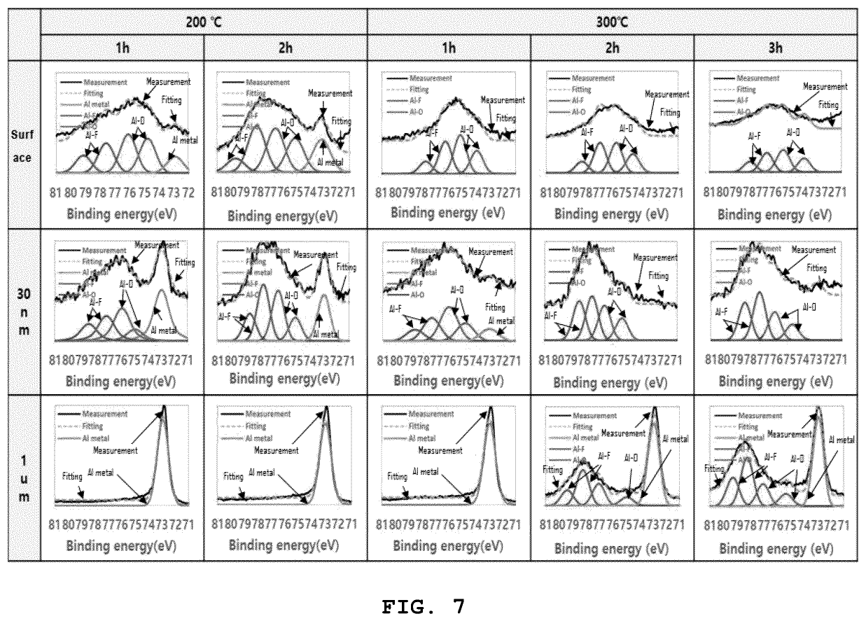

FIG. 4 is a table showing the results of comparing the surface microstructure and the Mg and F contents of the part depending on the plasma heat treatment temperature and the treatment time, FIG. 5 is a table showing the results of XRD analysis depending on the plasma heat treatment temperature and the treatment time, FIG. 6 is a table showing the results of XPS analysis for depth depending on the plasma heat treatment temperature and the treatment time, and FIG. 7 is a table showing the results of analyzing the binding energy of a protective fluoride layer depending on the plasma heat treatment temperature and the treatment time.

As shown in FIG. 4, as a result of analyzing the surface microstructure and the Mg and F contents of the part depending on the plasma heat treatment temperature and the treatment time, it was confirmed that the F content increased as the treatment temperature and the treatment time increased, but the Mg content of the Al alloy increased after 3 hours at 300° C., and the Mg content also increased at a treatment temperature of 400° C. or higher.

In addition, as shown in FIG. 5, as a result of XRD analysis depending on the plasma heat treatment temperature and the treatment time, it was confirmed that the F content and the thickness (depth) of the protective layer increased as the treatment time increased, and in particular, the F content increased when the treatment time was 3 hours or longer. Here, although the thickness did not appear to change at 3 hours or more on the graph because it could not be measured deeper due to the XPS depth measurement limit, it was determined that the thickness actually increased due to diffusion as the time increased.

In addition, as shown in FIG. 6, as a result of XPS analysis for depth depending on the plasma heat treatment temperature and the treatment time, it was confirmed that, when the reaction time was increased from 1 hour to 2 hours at 300° C., the AlF₃ phase intensity increased, and when the reaction time was increased from 2 hours to 3 hours at 300° C., the AlF₃ phase intensity did not change. That is, it was confirmed that, as the treatment time increased, the Al—F reaction layer became thicker due to the diffusion of F and the intensity of the Al metal decreased.

In addition, as shown in FIG. 7, as a result of analyzing the binding energy of the protective fluoride layer depending on the plasma heat treatment temperature and the treatment time, it was confirmed that Al—F and Al—O bonds were present on the surfaces of all specimens, indicating the Al—F reaction. In particular, it was confirmed that the Al—F binding energy was higher than the Al—O binding energy at a depth of 30 nm from the surface. In addition, it was confirmed that Al—F bonds existed up to a depth of 1 μm under the conditions of treatment temperature of 300° C. and treatment time of 2 hours or more, and that the thickness of the Al—F reaction layer increased as the treatment temperature increased.

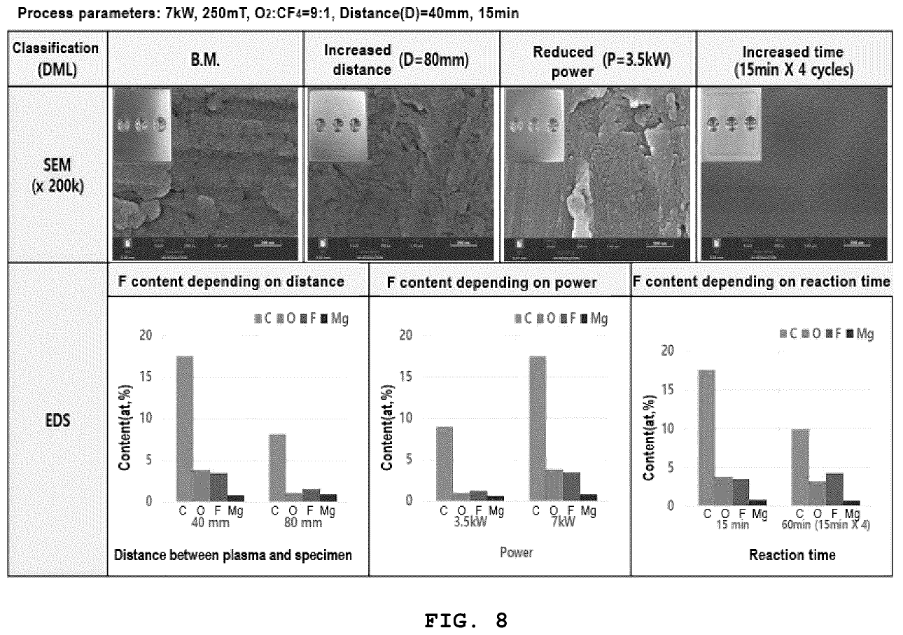

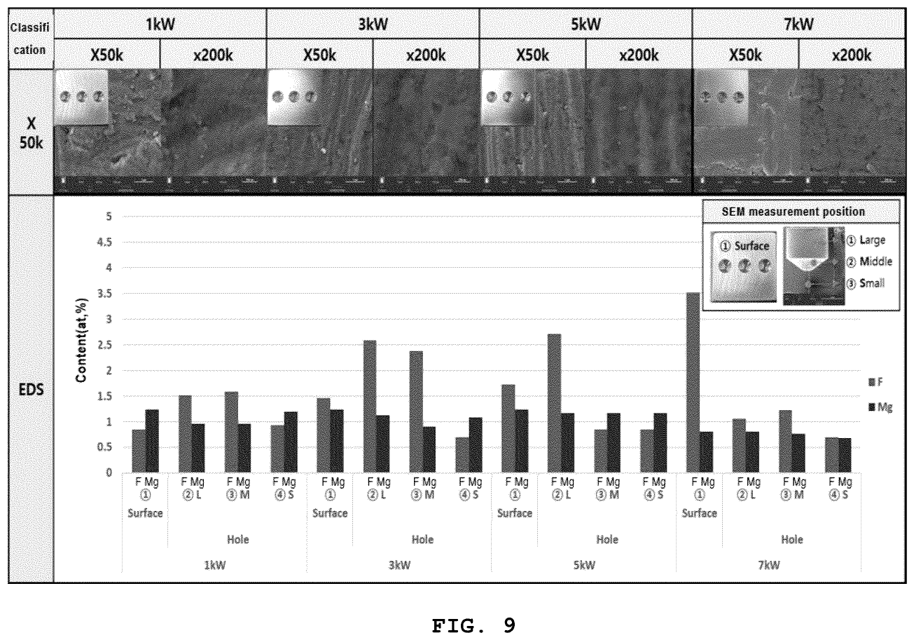

The results of experiments on the protective fluoride layer obtained through the method of forming for a protective fluoride layer using the process parameters of the second embodiment will now be described with reference to FIGS. 8 and 9.

FIG. 8 is a table showing the results of an experiment on the formation of a protective fluoride layer using the process parameters of the second embodiment, and FIG. 9 is a table showing the results of an experiment on the formation of a protective fluoride layer on the surface and in the holes using the process parameters of the second embodiment.

As shown in FIGS. 8 and 9, it was confirmed that, when the process parameters were in the ranges of the second embodiments, the F content increased not only on the surface of the Al showerhead but also in the holes. On the other hand, it was confirmed that, when the distance between plasma and the specimen increased outside of the range of the process parameter of the second embodiment and the reaction time and power decreased, the F content decreased on the surface of the Al showerhead and in the holes. When the reaction time at a certain level of high power increased, the F content on the surface decreased due to the occurrence of Al etching. Here, it was confirmed that the increase in the F content in the holes relative to that on the surface was due to the fact that direct ion collisions are less than on the surface, and thus etching did not occur and the F content increased.

According to the method for forming a protective fluoride layer on a part having a gas flow passage for a semiconductor deposition apparatus according to the present disclosure as described above and a part having a gas flow passage for a semiconductor deposition apparatus, which has a protective fluoride layer formed thereby, it is possible to form a stable protective fluoride layer on the surface and in the holes of a showerhead, which is a part having a gas flow passage and a plurality of gas injection holes, and it is possible to form the protective fluoride layer with a controlled content and/or thickness by controlling the heat treatment temperature and reaction time.

In addition, the present disclosure has advantages in that the amount of by-products and particles adhering to the surface or holes of a part having a gas flow passage is drastically reduced, it is possible to prevent a shift in process conditions from occurring when cleaning with a fluorine-containing cleaning gas (in-situ dry cleaning (ISD)), and it is possible to prevent the protective layer formed on the surface and in the holes of the part from being detached and protect the part from the plasma cleaning gas, thereby extending the life of the part.

What is claimed is:

1. A method for forming a protective fluoride layer on a part having a gas flow passage for a semiconductor deposition apparatus, the part including a showerhead having a gas flow passage and a plurality of holes, the method comprising:
a part placement step of placing a part having a gas flow passage in a process chamber;
a process gas introduction step of introducing process gases for forming a protective fluoride layer into the process chamber;
a plasma heat treatment step of applying heat and plasma to the process chamber; and
a process control step of controlling process parameters of the process gas introduction step and the plasma heat treatment step so that a protective fluoride layer with a predetermined thickness is formed on a surface of the part having the gas flow passage and in the gas flow passage and the holes.

2. The method according to claim 1, wherein the process control step comprises controlling a combination of a plurality of process parameters among process parameters, including process gas introduction amounts, plasma generation power, treatment time, heat treatment temperature, working vacuum level, a distance between the plasma and the part, and the number of treatment cycles.

3. The method according to claim 1, wherein the process control step comprises controlling the process parameters so that the protective fluoride layer is formed to a thickness of 200 nm to 500 nm.

4. The method according to claim 2, wherein the process control step comprises controlling the process parameters so that the protective fluoride layer is formed to a thickness of 200 nm to 500 nm.

5. The method according to claim 1, wherein the process parameters that are controlled in the process control step include a plasma generation power of 100 W, a heat treatment temperature of 200° C. to 600° C., a working vacuum level of 10 mTorr to 20 mTorr, and a treatment time of 1 hour to 3 hours.

6. The method according to claim 2, wherein the process parameters that are controlled in the process control step include a plasma generation power of 100 W, a heat treatment temperature of 200° C. to 600° C., a working vacuum level of 10 mTorr to 20 mTorr, and a treatment time of 1 hour to 3 hours.

7. The method according to claim 3, wherein the process parameters that are controlled in the process control step include a plasma generation power of 100 W, a heat treatment temperature of 200° C. to 600° C., a working vacuum level of 10 mTorr to 20 mTorr, and a treatment time of 1 hour to 3 hours.

8. The method according to claim 1, wherein the process parameters that are controlled in the process control step include a plasma generation power of 1 kW to less than 3 kW, a flow rate ratio between non-fluorine reactive gas (O₂) and fluorine-containing reactive gas (CF₄) of 0 to 10:90 to 100, a distance between the plasma and the part of 30 to 50 mm, a treatment time of 15 to 60 minutes, and a cycle number of 1 to 4 cycles, and the process control step is performed using a floating plasma source method for forming a floating potential.

9. The method according to claim 2, wherein the process parameters that are controlled in the process control step include a plasma generation power of 1 KW to less than 3 KW, a flow rate ratio between non-fluorine reactive gas (O₂) and fluorine-containing reactive gas (CF₄) of 0 to 10:90 to 100, a distance between the plasma and the part of 30 to 50 mm, a treatment time of 15 to 60 minutes, and a cycle number of 1 to 4 cycles, and the process control step is performed using a floating plasma source method for forming a floating potential.

10. A part having a gas flow passage for a semiconductor deposition apparatus, which has a protective fluoride layer formed by the method according to claim 1.

11. An apparatus for forming a protective fluoride layer on a part having a gas flow passage for a semiconductor deposition apparatus, the part including a showerhead having a gas flow passage and a plurality of holes, the apparatus for forming the protective fluoride layer comprising:
a process chamber body;
a process gas inlet provided on one side of the process chamber body and configured to introduce process gases;
a process gas outlet provided on the other side of the process chamber body and configured to discharge process gases;
a heating member provided in the process chamber body; and
a power electrode member provided in the process chamber body.

12. The apparatus according to claim 11, wherein the process gas inlet is provided at a central portion of an upper side of the process chamber body, the process gas outlet is provided at a central portion of a lower side of the process chamber body, and the power electrode member is provided opposite to the heating member at a predetermined distance therefrom.

13. The apparatus according to claim 11, wherein the power electrode member is composed of a plurality of ring-shaped electrodes arranged at a distance from each other in a radial direction concentrically around a center of the process chamber body.

14. The apparatus according to claim 12, wherein the power electrode member is composed of a plurality of ring-shaped electrodes arranged at a distance from each other in a radial direction concentrically around a center of the process chamber body.

15. The apparatus according to claim 11, wherein the power electrode member has a spiral shape, a coil shape, or a plate shape.

16. The apparatus according to claim 12, wherein the power electrode member has a spiral shape, a coil shape, or a plate shape.

17. The apparatus according to claim 11, wherein the heating member is composed of a plate-shaped heater on which the part having the gas flow passage is placed.

18. The apparatus according to claim 12, wherein the heating member is composed of a plate-shaped heater on which the part having the gas flow passage is placed.

19. The apparatus according to claim 11, further comprising, at a process gas inlet side, a diffusion member that allows the process gases introduced through the process gas inlet to diffuse.

20. The apparatus according to claim 12, further comprising, at a process gas inlet side, a diffusion member that allows the process gases introduced through the process gas inlet to diffuse.
